(19) United States
(12) Patent Application Publication
(10) Pub. No.: US 2025/0103035 A1
(43) Pub. Date: Mar. 27, 2025

(54) METHOD AND SYSTEM FOR DETECTING ANOMALY IN TIME SERIES DATA

(71) Applicant: Elisa Oyj, Helsinki (FI)

(72) Inventors: Eero Hiltunen, Helsinki (FI); Rasmus Heikkilä, Helsinki (FI); Nils Knoblauch, Helsinki (FI)

(73) Assignee: Elisa Oyj, Helsinki (FI)

(21) Appl. No.: 18/728,231

(22) PCT Filed: Feb. 27, 2023
(86) PCT No.: PCT/FI2023/050109

§ 371 Date: Jul. 11, 2024

(30) Foreign Application Priority Data
Mar. 14, 2022 (FI) 20225225

(51) Int. Cl. G05B 23/02; G06N 3/0455

(52) U.S. Cl. CPC G05B 23/024; G05B 23/0254; G06N 3/0455

(57) ABSTRACT

A method and a system for detecting an anomaly in sensor time series data of a sensing arrangement includes implementing a neural network trained on training data with prior sensor time series data; re-constructing a sample sensor time series data for a target time period using the trained neural network; determining an anomaly score variable based on a re-construction error in the re-constructed sample sensor time series data; determining a confidence interval for the target time period based on a distribution of the determined anomaly score variable; mapping a target sensor time series data, generated by the sensing arrangement corresponding to the target time period, to the determined confidence interval; and indicating an anomaly in the target sensor time series data if the target sensor time series data is not substantially within the determined confidence interval.

### TECHNICAL FIELD

The present disclosure relates generally to anomaly detection in time series data; and more specifically, to a method and a system for detecting an anomaly in sensor time series data of a sensing arrangement integrated with a statistical process control of a semiconductor manufacturing process.

### BACKGROUND

Semiconductor manufacturing processes require constant monitoring. In such processes, processing conditions change over time with the slightest changes in critical process parameters. For example, small changes can easily occur in the composition or pressure of an etch gas, process chamber, or wafer temperature. These changes in processing conditions may, in turn, create undesirable results, like semiconductor manufacturing defects. A process of semiconductor manufacturing often requires hundreds of sequential steps, each one of which could lead to a yield loss. Consequently, maintaining product quality in a semiconductor manufacturing facility often requires a strict control of hundreds or even thousands of process variables. The process variables are the variables which can be adjusted by a control computing system to ensure a product quality and yield rate of semiconductor chips manufactured by the semiconductor manufacturing process.

With rapid growth of sensor and measurement technologies, an abundance of process data is available in real-time for semiconductor manufacturing processes. For instance, trace data is sensor data logged by many different sensors during one or more processing steps in a semiconductor manufacturing process. In other words, trace data includes signals measured from the sensors mounted on manufacturing tools in semiconductor processing. This abundance of the sensor data provides an opportunity to develop a systematic performance prediction and monitoring approach to capture an underlying process complexity and enhances a process control capability. In conventional approach, the anomaly detection is performed manually by domain experts based on the level of expertise and knowledge in respective domains and thereby addressed as per requirement (such as, by service personnel or domain experts), thereby making the process time-consuming and complex, and prone to significant inaccuracies, specially while maintaining complex manufacturing processes such as semiconductor manufacturing process which often requires a strict control of hundreds or even thousands of process variables.

As discussed, the semiconductor manufacturing process includes multiple manufacturing steps, e.g., etching, chemical deposition, CMP (Chemical-Mechanical Planarization-a step for smoothing surfaces of a semiconductor wafer), which exhibit non-linearity and non-stationarity characteristics. These multiple manufacturing steps accommodate a time-varying nature, e.g., sensor data from these manufacturing steps would vary from time to time. Therefore, with existing techniques, it may not even be possible to detect anomalies in sensor time series data generated by such sensors by simply referring to the sensor time series data; which, in many cases, may be indicative of and thus help in detecting deterioration of processing characteristics.

There are some existing techniques, not necessarily applied for anomaly detection in a process, let alone for anomaly detection in the semiconductor manufacturing process, which use confidence interval of variables in the sensor time series data but none of these may consider co-relation of variables or auto-correlation of time series. For instance, there are forecast models, implementing LSTM (Long Short-Term Memory) and/or ARIMA (Auto-Regressive Integrated Moving Average) which may determine confidence interval based on prediction errors. However, these models does not work if there is no seasonality or easy predictability in the sensor time series data, and may certainly not be applicable to time-varying discrete manufacturing processes, such as the semiconductor manufacturing process. There are other approaches involving supervised regression models, but these get highly complex for multi-dimensional time series data, as those may require corresponding number of models to the multi-dimensional time series data to be defined. Further, there are some known techniques which determines anomaly metric for a time series data based on Mahalanobis distance or using mean-squared-error over time period. However, in such examples, the determined anomaly metric describes the anomality of the process but does not provide any justification/explanation for anomalies. Furthermore, there are known models which implement SHAP (SHapley Additive explanations), which is a game theoretic approach to explain the output of any machine learning model, to explain anomalies in the time series data. But this approach is slow to compute due to kernel SHAP approximation and lacks visual aspect.

Therefore, in light of the foregoing discussion, there exists a need to overcome the aforementioned drawbacks associated with the conventional semiconductor manufacturing process, and provide a method and a system for detecting an anomaly in sensor time series data of a sensing arrangement which may be integrated with a statistical process control of a semiconductor manufacturing process.

### SUMMARY OF THE INVENTION

The present disclosure seeks to provide a method for detecting an anomaly in sensor time series data of a sensing arrangement. The present disclosure also seeks to provide a system for detecting an anomaly in sensor time series data of a sensing arrangement integrated with a statistical process control of a process. An aim of the present disclosure is to provide a solution that overcomes at least partially the problems encountered in prior art. In particular, to overcome the aforementioned problems, the system and the method of the present disclosure enables automatic and near real-time detection of anomalies in multi-dimensional sensor time series data of a sensing arrangement by implementing a neural network trained on training data comprising prior sensor time series data, and thereby beneficially provide a time-effective and efficient operation as compared to the conventional approaches.

In one aspect, an embodiment of the present disclosure provides a method for detecting an anomaly in sensor time series data of a sensing arrangement, via a processing unit, the method comprising:
implementing a neural network trained on training data comprising prior sensor time series data;
re-constructing a sample sensor time series data for a target time period using the trained neural network;
determining an anomaly score variable based on a re-construction error in the re-constructed sample sensor time series data, corresponding to each of a plurality of time instants in the target time period;
determining a confidence interval for the target time period based on a distribution of the determined anomaly score variable;
mapping a target sensor time series data, generated by the sensing arrangement corresponding to the target time period, to the determined confidence interval; and
indicating an anomaly in the target sensor time series data if the target sensor time series data is not substantially within the determined confidence interval,
characterised in that the anomaly score variable is determined based on a maximum absolute reconstruction error in the re-constructed sample sensor time series data.

In another aspect, an embodiment of the present disclosure provides a system comprising:
a sensing arrangement integrated with a statistical process control of a semiconductor manufacturing process, the sensing arrangement configured to generate sensor time series data for the process;
a neural network trained on training data comprising prior sensor time series data, the neural network configured to re-construct a sample sensor time series data for a target time period; and
a processing unit configured to:
   determine an anomaly score variable based on a re-construction error in the re-constructed sample sensor time series data, corresponding to each of a plurality of time instants in the target time period;
   determine a confidence interval for the target time period based on a distribution of the determined anomaly score variable;
   map a target sensor time series data, generated by the sensing arrangement corresponding to the target time period, to the determined confidence interval; and
   indicate an anomaly in the target sensor time series data if the target sensor time series data is not substantially within the determined confidence interval,
characterised in that the processing unit (130) is configured to determine the anomaly score variable based on a maximum absolute reconstruction error in the re-constructed sample sensor time series data.

In yet another aspect, an embodiment of the present disclosure provides a computer program comprising computer executable program code which when executed by a processor causes a system to perform the method as described above.

Embodiments of the present disclosure substantially eliminate or at least partially address the aforementioned problems in the prior art and enable automation of the anomaly detection and thereby the modification of the device using detected anomalous behaviour.

Additional aspects, advantages, features and objects of the present disclosure would be made apparent from the drawings and the detailed description of the illustrative embodiments construed in conjunction with the appended claims that follow.

It will be appreciated that features of the present disclosure are susceptible to being combined in various combinations without departing from the scope of the present disclosure as defined by the appended claims.

### BRIEF DESCRIPTION OF THE DRAWINGS

The summary above, as well as the following detailed description of illustrative embodiments, is better understood when read in conjunction with the appended drawings. For the purpose of illustrating the present disclosure, exemplary constructions of the disclosure are shown in the drawings. However, the present disclosure is not limited to specific methods and instrumentalities disclosed herein. Moreover, those skilled in the art will understand that the drawings are not to scale. Wherever possible, like elements have been indicated by identical numbers.

Embodiments of the present disclosure will now be described, by way of example only, with reference to the following diagrams wherein:

FIG. 1 is a block diagram illustration of a system for modifying a state of a device using detected anomalous behaviour in a self-exciting point process, in accordance with an embodiment of the present disclosure;

FIG. 2 is an illustration of a flowchart listing steps involved in a method for detecting an anomaly in sensor time series data of a sensing arrangement, in accordance with an embodiment of the present disclosure;

FIG. 3 is an exemplary schematic illustration of a neural network, in accordance with an embodiment of the present disclosure;

FIG. 4 is an exemplary schematic illustration of a process for defining confidence interval for a target time period, in accordance with an embodiment of the present disclosure; and

FIGS. 5A and 5B are exemplary graphical illustrations of a target sensor time series data mapped to confidence interval for two different process cycles, for detecting anomaly in the target sensor time series data, in accordance with various embodiments of the present disclosure.

In the accompanying drawings, an underlined number is employed to represent an item over which the underlined number is positioned or an item to which the underlined number is adjacent. A non-underlined number relates to an item identified by a line linking the non-underlined number to the item. When a number is non-underlined and accompanied by an associated arrow, the non-underlined number is used to identify a general item at which the arrow is pointing.

### DETAILED DESCRIPTION OF EMBODIMENTS

The following detailed description illustrates embodiments of the present disclosure and ways in which they can be implemented. Although some modes of carrying out the present disclosure have been disclosed, those skilled in the art would recognize that other embodiments for carrying out or practising the present disclosure are also possible.

In one aspect, an embodiment of the present disclosure provides a method for detecting an anomaly in sensor time series data of a sensing arrangement, the method comprising:
implementing a neural network trained on training data comprising prior sensor time series data;
re-constructing a sample sensor time series data for a target time period using the trained neural network;
determining an anomaly score variable based on a re-construction error in the re-constructed sample sensor time series data, corresponding to each of a plurality of time instants in the target time period;
determining a confidence interval for the target time period based on a distribution of the determined anomaly score variable;
mapping a target sensor time series data, generated by the sensing arrangement corresponding to the target time period, to the determined confidence interval; and
indicating an anomaly in the target sensor time series data if the target sensor time series data is not substantially within the determined confidence interval.

In another aspect, an embodiment of the present disclosure provides a system comprising:
a sensing arrangement integrated with a statistical process control of a process, the sensing arrangement configured to generate sensor time series data for the process;
a neural network trained on training data comprising prior sensor time series data, the neural network configured to re-construct a sample sensor time series data for a target time period; and
a processing unit configured to:
   determine an anomaly score variable based on a re-construction error in the re-constructed sample sensor time series data, corresponding to each of a plurality of time instants in the target time period;
   determine a confidence interval for the target time period based on a distribution of the determined anomaly score variable;
   map a target sensor time series data, generated by the sensing arrangement corresponding to the target time period, to the determined confidence interval; and
   indicate an anomaly in the target sensor time series data if the target sensor time series data is not substantially within the determined confidence interval.

In yet another aspect, an embodiment of the present disclosure provides a computer program comprising computer executable program code which when executed by a processor causes a system to perform the method as described above.

The present disclosure provides a method and a system for detecting an anomaly in time series data, such as sensor time series data of a process, like a statistical process control of a semiconductor manufacturing process. The system of the present disclosure comprises a processing unit which performs the necessary processing steps for analysing the sensor time series data, for detecting the anomalies therein. Herein, the “processing unit” refers to a computational element that is operable to respond to and processes instructions that drive the system for modifying a state of a device using detected anomalous behaviour in a self-exciting point process. In an embodiment, the processing unit includes, but is not limited to, a microprocessor, a microcontroller, a complex instruction set computing (CISC) microprocessor, a reduced instruction set (RISC) microprocessor, a very long instruction word (VLIW) microprocessor, or any other type of processing circuit. Furthermore, the term “processing unit” may refer to one or more individual processors, processing devices and various elements associated with a processing device that may be shared by other processing devices. Additionally, the one or more individual processors, processing devices and elements are arranged in various architectures for responding to and processing the instructions that drive the system.

Herein, the term “time series data” refers to a dataset or a series of data points (or point values) indexed (or listed or graphed) in a temporal order. The time series data is a sequence taken at successively spaced time instants of the time period and comprises a sequence of discrete-point values for respective time instants of the time period for a process. Optionally, the time instants are spaced at equal intervals. Optionally, the time instants are spaced at varying intervals. Generally, the time series data includes large volumes of data having a high dimensionality, wherein the data in the time series is added and analysed dynamically as time progresses. Moreover, the time series may be updated in real time, specifically at the successively spaced points values or time instants. Herein, the time series data is associated with a time period comprising a plurality of time periods comprising point values for respective time instants for the self-exciting process. Typically, the received time series data may be associated with an operation or performance of the process and thereby analysing and/or processing the received time series data via the method enables detection of anomalies associated with the process.

Further, herein, the term “anomaly” has been used to refer to a behaviour deviating from a normal or expected behaviour, suggesting an underlying issue that leads to the generation of the anomaly. The present disclosure is configured to identify data points, events, and/or observations in the sensor time series data that deviate from normal behaviour i.e., exhibit anomalous behaviour, wherein the anomalous behaviour indicates critical incidents, such as technical issues or glitches, for instance, in the semiconductor manufacturing process. In particular, the detected anomaly present in the sensor time series data of a specific sensor, which may be associated with, for example, a tool or a component responsible for a particular manufacturing step in the semiconductor manufacturing process, may be indicative of some issues with the corresponding tool or component.

For the purposes of the present disclosure, the system comprises a sensing arrangement integrated with a statistical process control of a process. In the present examples, in which the method and the system of the present disclosure are being implemented for detecting anomalies in sensor time series data of the semiconductor manufacturing process, the sensing arrangement is integrated with the statistical process control of the semiconductor manufacturing process. That is, the sensing arrangement may be integrated with manufacturing site of semiconductors as part of integrated statistical process control. Herein, the sensing arrangement may capture data that illustrates how the components in a design are operating, executing, and performing. The ability to trace a target depends on what trace facilities the target offers. In the semiconductor manufacturing process, to trace usually involves a separate trace generation component for each type of trace that is performed. For example, different trace sources produce processor trace and bus trace. Other examples in which the method and system of the present disclosure can be applied are any system comprising a set of sensors monitoring environment, as an example a cellular network having a set of base stations monitoring for example humidity and temperature of components of the base stations. Technical effect of integrating to a statistical process control is that the possible changes in the system are more valid i.e. control takes place only when a real anomality is present. This for example eliminates unneeded controls which could arise from random noise in some sensor or error in data communication which would indicate a false reading.

The sensing arrangement is configured to generate the requisite sensor time series data for the process, for which the sensor time series data needs to be analysed for detecting the anomalies therein. In some embodiments, the sensing arrangement comprises a plurality of sensor devices, and wherein the sensor time series data comprises sensor parameters with timestamps for each of the plurality of sensor devices (i.e., sensor trace data with time dimension). In particular, herein, the sensing arrangement may include multiple sensors, each of which may be associated with, such as mounted on, one of manufacturing tools and components in the semiconductor processing of the semiconductor manufacturing process. Each of the multiple sensors in the sensing arrangement may generate sensor data with time dimension for the corresponding manufacturing tool or component, where the sensor data is the trace data comprising logging information of process operation that does not interfere with the process itself.

The system and the method of the present disclosure implements a neural network which is disposed in data communication with the sensing arrangement. The neural network may receive instances of sensor time series data from the sensing arrangement. In particular, the neural network may receive prior sensor time series which may be sensor time series data corresponding to a prior (sample) time period to a target time period for which the corresponding target sensor time series data needs to be analysed for detecting the anomalies therein. In one or more embodiments of the present disclosure, the neural network is an autoencoder comprising an encoder and a decoder, and wherein the encoder is trained on the training data and the decoder is implemented to re-construct the sample sensor time series data. The described autoencoder utilizing the encoder and the decoder may be contemplated by a person skilled in the art and thus has not been described in detail herein for the brevity of the present disclosure. Such autoencoder may be able to “predict” sequences that are unpredictable for forecasting models (such as ARIMA, RNN forecast, moving-average). Further, such autoencoder also works with short and long cycles/runs of the sensor time series data as would be required for implementation of embodiments of the present disclosure.

The method comprises implementing the neural network trained on training data comprising the prior sensor time series data. That is, herein, the neural network is trained on training data comprising the prior sensor time series data. According to embodiments of the present disclosure, the neural network would need to predict “normal” instances of sensor time series data for the target time period, as would be discussed later in the disclosure in detail. For this purpose, the neural network may need to be trained on sensor time series data representing normal operating conditions (NOC) for the process to be analysed. Thus, herein, the prior sensor time series data may be selected from available multiple instances of sensor time series data, as generated by the sensing arrangement, representing the normal operating conditions for the process to be analysed for detecting the anomalies therein. Herein, selecting the prior sensor time series data, from the received time-series data, may be based on characterizing a normal behaviour for the sensor trace data for at least a defined time period of the process. This may involve characterizing the normal behaviour of each time series (or portion thereof) in the time series data. In an example, the normal time series behaviour may be characterized by a relatively stationary curve, i.e., trend and volatility are almost constant, in which the stationary trend may be modelled via plurality of modelling means to define a prediction interval.

The method further comprises re-constructing a sample sensor time series data for the target time period using the trained neural network. In other words, the neural network is configured to re-construct the sample sensor time series data for the target time period. That is, the neural network is trained to predict instances of “normal” time series data for the target time period, with the target time period being the input time period itself for the neural network. It may be appreciated that the described neural network trained using only the time series data sequences corresponding to the normal operating conditions may only be able to re-construct (by predicting) “normal” time series data for the target time period. This is possible since the neural network would only be trained on the normal operating conditions' time series data and would thus only be able to predict sensor time series data related to the normal operating conditions. It may be understood that, herein, the use of term “predicting” does not necessarily mean forecasting in future time but may be understood as predicting some variable based on other variables.

The method further comprises determining an anomaly score variable based on a re-construction error in the re-constructed sample sensor time series data, corresponding to each of a plurality of time instants in the target time period. Herein, the processing unit is configured to determine an anomaly score variable based on a re-construction error in the re-constructed sample sensor time series data, corresponding to each of a plurality of time instants in the target time period. As discussed, the described neural network trained using only the time series data sequences corresponding to normal operating conditions may only be able to re-construct “normal” time series data for the target time period. Now, when such neural network is given an anomalous sequence, the neural network may not be able to reconstruct it well, and hence would lead to higher reconstruction errors compared to the reconstruction errors for the normal sequences; which in turn may be utilized to detect anomalies in a target sensor time series data, which is the sensor time series data for the said target time period (as discussed later in the disclosure).

In an embodiment, re-constructing the sample sensor time series data using the neural network comprises predicting at least one variable and a corresponding timestamp for each of the plurality of time instants in the target time period. Herein, the neural network is configured to predict at least one variable and a corresponding timestamp for each of the plurality of time instants in the target time period, to re-construct the sample sensor time series data. That is, each variable and timestep in the sensor time series data receives a unique prediction/reconstruction by the neural network.

In one or more embodiments, the anomaly score variable is determined based on a maximum absolute reconstruction error in the re-constructed sample sensor time series data. Herein, the processing unit is configured to determine the anomaly score variable based on a maximum absolute reconstruction error in the re-constructed sample sensor time series data. That is,
anomaly_score_variable=max (abs(recons_error)).

Such maximum absolute reconstruction error helps to define a threshold for variables in the sensor time series data and may thus be used for constructing the confidence intervals for visualizations, as described in the proceeding paragraphs. In the present embodiments, the maximum absolute reconstruction error may be per variable or per variable timestep. In the latter case, the width of the confidence interval depends on the time step. It may be appreciated that herein, for example, high mean absolute reconstruction error may not be attributable to any specific time step but the entire time series; and thus may not be suitable for constructing the confidence intervals for visualizations.

The method further comprises determining a confidence interval for the target time period based on a distribution of the determined anomaly score variable. Herein, the processing unit is configured to determine a confidence interval for the target time period based on a distribution of the determined anomaly score variable. As used herein, the “confidence interval” indicates a probability that a parameter will fall between a pair of values around the mean. In other words, the confidence interval measures the degree of uncertainty or certainty of the anomaly in the process being analysed.

In an embodiment, the confidence interval for the trained neural network is determined based on a mean of the determined anomaly score variable and a standard deviation of the determined anomaly score variable. Herein, the processing unit is configured to determine the confidence interval for the trained neural network based on a mean of the determined anomaly score variable and a standard deviation of the determined anomaly score variable. In an example, upper and lower limits of threshold based on a desired confidence level, which defines the confidence interval, may be determined as:

$$threshold = mean ( anomaly\_score \_variable ) + 3 * stdev ( anomaly\_score \_variable )$$

In the present embodiments, all variables may have their corresponding confidence interval width. It may be understood that the maximum absolute reconstruction error relates to the maximum absolute error of a variable inside a sensor time series data. It may also be understood that there may be multiple time series data and hence number of maximum absolute reconstruction errors. Therefore, herein, the mean of the anomaly score variable relates to the mean of the maximum absolute reconstruction errors across multiple time series. Similarly, the standard deviation of the determined anomaly score variable may be taken across multiple time series.

The method further comprises mapping a target sensor time series data, generated by the sensing arrangement corresponding to the target time period, to the determined confidence interval. Herein, the processing unit is configured to map a target sensor time series data, generated by the sensing arrangement corresponding to the target time period, to the determined confidence interval. As discussed, in the present disclosure, the error in prediction at any future time instance is used to compute the likelihood of anomaly in the sensor time series data corresponding to the target time period. It may be appreciated that the described neural network trained using only the time series data sequences corresponding to normal operating conditions may be used for detecting anomalies in multi-sensor time-series. This is possible since the neural network would only be trained on the normal operating conditions' time series data and would thus only be able to predict them. When given an anomalous sequence, the neural network may not be able to reconstruct it well, and hence would lead to higher reconstruction errors compared to the reconstruction errors for the normal sequences; which in turn could be utilized to detect anomalies in a target sensor time series data, which is the sensor time series data for the said target time period. Herein, mapping of the mapping a target sensor time series data, generated by the sensing arrangement corresponding to the target time period, to the determined confidence interval helps with such analysis, as described hereinafter.

The method further comprises indicating an anomaly in the target sensor time series data if the target sensor time series data is not substantially within the determined confidence interval. Herein, the processing unit is configured to indicate an anomaly in the target sensor time series data if the target sensor time series data is not substantially within the determined confidence interval. That is, if the datapoint(s) at any time instant in the target time period may be outside of the defined confidence interval (i.e., beyond the defined upper and lower thresholds), then it may be determined that the target sensor time series data may have an anomalous behaviour. It may be understood that such analysis (comparison) may be carried out independently for each of the variables of the target sensor time series data. According to an embodiment the indicated anomality in the target sensor can be used to trigger an action. The action can be for example adjusting process, creating an alert, initiating an error check of the related target sensor to see if the target sensor is functioning or not. One example could be that the anomality in the target sensor is indicating higher temperature than anticipated. This can be used to trigger start of cooling system related to equipment (or environment) associated with the target sensor. In other example the indication of anomality of drop of partial pressure of certain gas in atmosphere of a manufacturing process. In this case an alert to check the gas supply can be provided or gas flow of the said gas can be adjusted or the process might be stopped temporarily.

In another aspect, the present disclosure also provides computer program comprising computer executable program code which, when executed by a processor, causes a system to carry out the steps of the method for modifying the state of the device using detected anomalous behaviour in the self-exciting point process. Such computer executable program code may be stored on a memory. The “memory” as used herein refers to a computer readable storage medium for providing a non-transient memory may include, but is not limited to, an electronic storage device, a magnetic storage device, an optical storage device, an electromagnetic storage device, a semiconductor storage device, or any suitable combination of the foregoing, in which a computer can store data or software for any duration. In an embodiment, the memory is a. Furthermore, a single memory may encompass and, in a scenario, in case the system is distributed, the processing, memory and/or storage capability may be distributed as well. In an embodiment, the memory is a non-volatile mass storage such as physical storage media or a non-transitory computer-readable storage medium including, but not limited to, Electrically Erasable Programmable Read-Only Memory (EEPROM), Random Access Memory (RAM), Read Only Memory (ROM), Hard Disk Drive (HDD), Flash memory, a Secure Digital (SD) card, Solid-State Drive (SSD), a computer readable storage medium, and/or CPU cache memory.

The system and the method of the present disclosure allows the computation of confidence intervals (or safe zones) for multidimensional time series data from reconstruction errors of deep neural network autoencoder. The computed confidence intervals provide a clear explanation for alerts of autoencoder anomaly detection model and help the domain expert to analyse the cause for fault state. The system and the method of the present disclosure may be used in both short and long (time) processes, interval data can be determined, e.g., up to 1 per second. The present disclosure provides autoencoder based anomaly detection which has several benefits over conventional approaches such as statistics and forecasting models, such as multi-dimensional modelling and well explained predictions for the target time series data. The use of confidence intervals provide autoencoder reconstructions to visual confidence intervals and thus helps to depict the normal operation condition area clearly to the user, which in turn helps build trust between the user and the machine learning model.

According to one embodiment the indicated anomaly in the target sensor time series data is used to control the process. This way process can be improved in more reliable manner. For example a process control can be carried out for the indicated animalities which are relevant, not for example sensor readings arising from random noise or communication errors on reading sensor readings.

It may be appreciated that although the present disclosure has been described in terms of detecting anomalies in the sensor time series data of a semiconductor manufacturing process, the teachings of the present disclosure may be implemented for suitable mechanical devices, such as engines, vehicles, aircrafts, cellular network components etc., which are typically instrumented with numerous sensors to capture the behaviour and health of the machine. It may be understood that in such cases, there are often external factors or variables which are not captured by sensors leading to time-series which are inherently unpredictable; for instance, manual controls and/or unmonitored environmental conditions or load may lead to inherently unpredictable time-series.

### DETAILED DESCRIPTION OF THE DRAWINGS

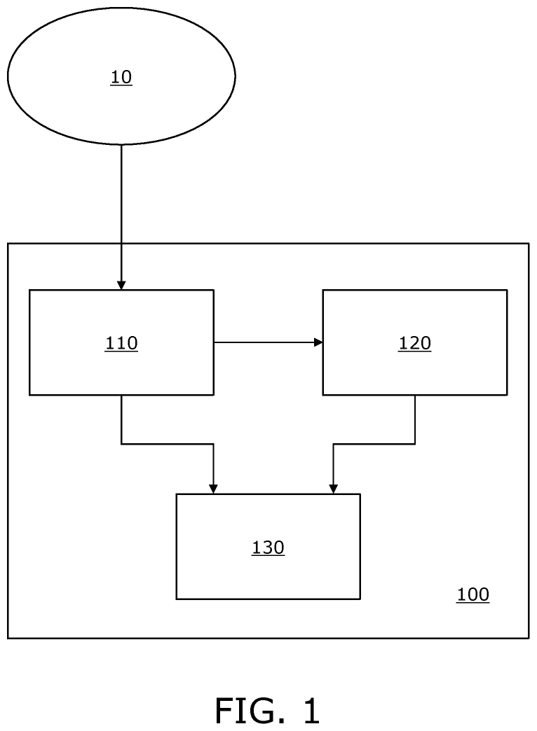

Referring to FIG. 1, illustrated is a schematic illustration of a block diagram of a system 100 for detecting an anomaly in sensor time series data of a sensing arrangement 110, in accordance with an embodiment of the present disclosure. As shown, the sensing arrangement 110 is integrated with a statistical process control 10 of a process, such as a semiconductor manufacturing process. The sensing arrangement 110 is configured to generate sensor time series data for the process. The system 100 includes a neural network 120 in data communication with the sensing arrangement 110 to receive training data comprising prior sensor time series data, as generated by the sensing arrangement 110. The neural network 120 is trained on training data comprising prior sensor time series data. The neural network 120 is configured to re-construct a sample sensor time series data for a target time period. The system 100 further includes a processing unit 130. The processing unit 130 is configured to determine an anomaly score variable based on a re-construction error in the re-constructed sample sensor time series data, corresponding to each of a plurality of time instants in the target time period; determine a confidence interval for the target time period based on a distribution of the determined anomaly score variable; map a target sensor time series data, generated by the sensing arrangement 110 corresponding to the target time period, to the determined confidence interval; and indicate an anomaly in the target sensor time series data if the target sensor time series data is not substantially within the determined confidence interval.

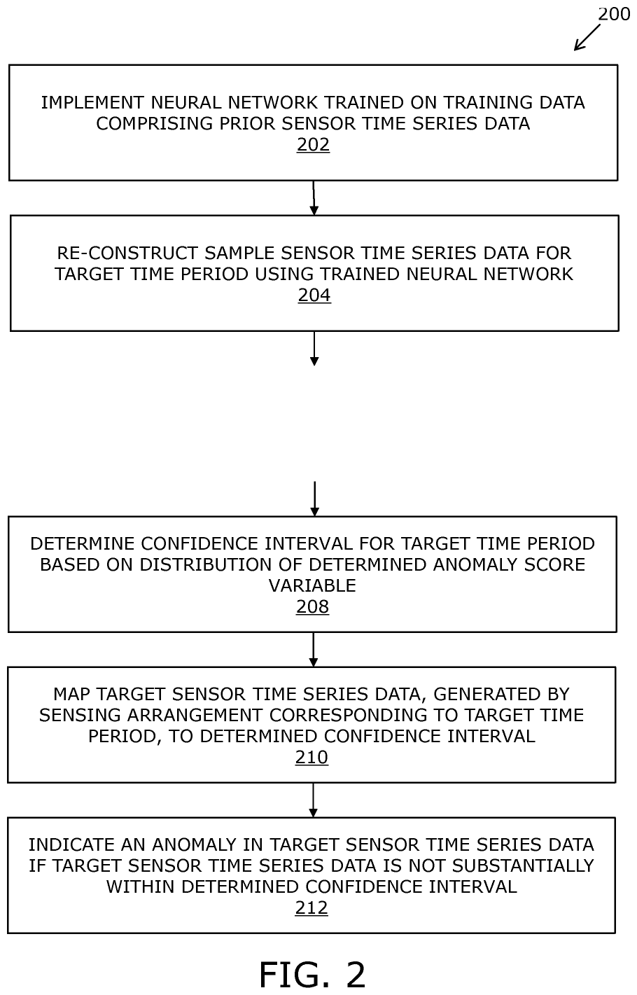

Referring to FIG. 2, illustrated is a flowchart listing steps involved in a method 200 for detecting an anomaly in sensor time series data of a sensing arrangement (such as, the sensing arrangement 110), in accordance with an embodiment of the present disclosure. At a step 202, the method 200 comprises implementing a neural network trained on training data comprising prior sensor time series data. At a step 204, the method 200 comprises re-constructing a sample sensor time series data for a target time period using the trained neural network. At a step 206, the method 200 comprises determining an anomaly score variable based on a re-construction error in the re-constructed sample sensor time series data, corresponding to each of a plurality of time instants in the target time period. At a step 208, the method 200 comprises determining a confidence interval for the target time period based on a distribution of the determined anomaly score variable. At a step 210, the method 200 comprises mapping a target sensor time series data, generated by the sensing arrangement corresponding to the target time period, to the determined confidence interval. And, at a step 212, the method 200 comprises indicating an anomaly in the target sensor time series data if the target sensor time series data is not substantially within the determined confidence interval. It may be appreciated that the steps 202 to 212 are only illustrative, and other alternatives can also be provided where one or more steps are added, one or more steps are removed, or one or more steps are provided in a different sequence without departing from the scope of the present disclosure.

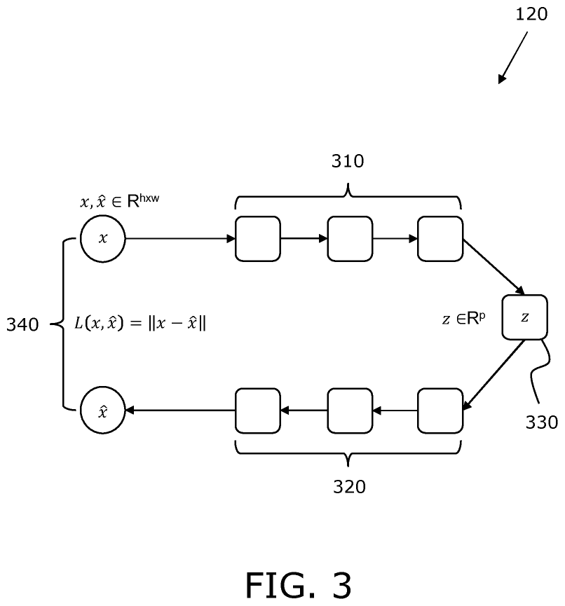

Referring to FIG. 3, illustrated is an exemplary schematic illustration of the neural network 120 of FIG. 1, in accordance with an embodiment of the present disclosure. Herein, the neural network 120 is in the form of an autoencoder comprising an encoder 310 and a decoder 320. The encoder 310 is trained on the training data and the decoder 320 is implemented to re-construct the sample sensor time series data. In particular, the encoder 310 generates a compressed representation (as indicated by the reference numeral 330) of the training data and attempts to learn from it. Further, the decoder 320 attempts to re-construct the sample sensor time series data based on the learning while minimizing reconstruction loss (as indicated by the reference numeral 340).

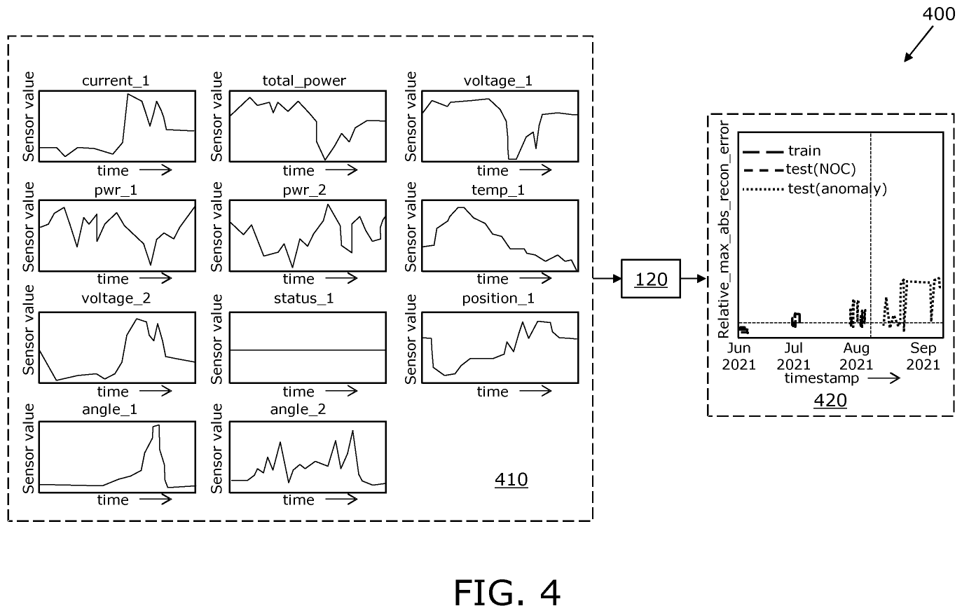

Referring to FIG. 4, illustrated is an exemplary schematic illustration of a process 400 for defining confidence interval for a target time period, in accordance with an embodiment of the present disclosure. As shown, first, in the process 400, a training data 410 is received. The training data 410 comprises prior sensor time series data, which is the sensor time series data representing normal operating conditions (NOC) for the process to be analysed. Further, in the process 400, the training data 410 is fed to the neural network 120 (as described above). Further, in the process 400, the neural network 120 re-construct a sample sensor time series data (as indicated by the reference numeral 420) for a target time period. Herein, the sample sensor time series data 420 helps to determine an anomaly score variable based on a re-construction error in the re-constructed sample sensor time series data, corresponding to each of a plurality of time instants in the target time period, which is further used to determine a confidence interval for the target time period based on a distribution of the determined anomaly score variable.

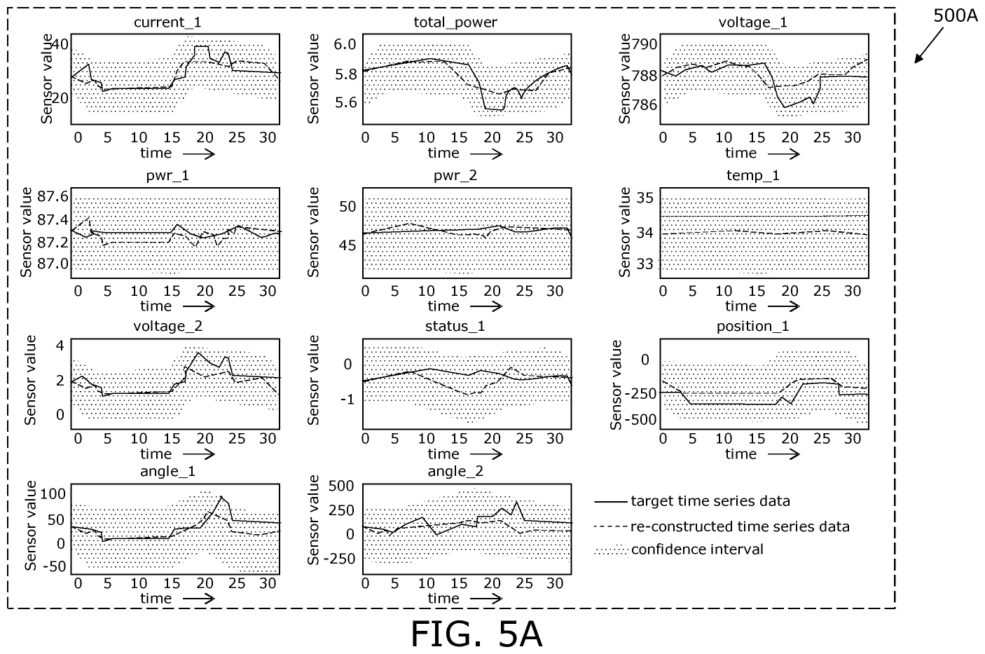

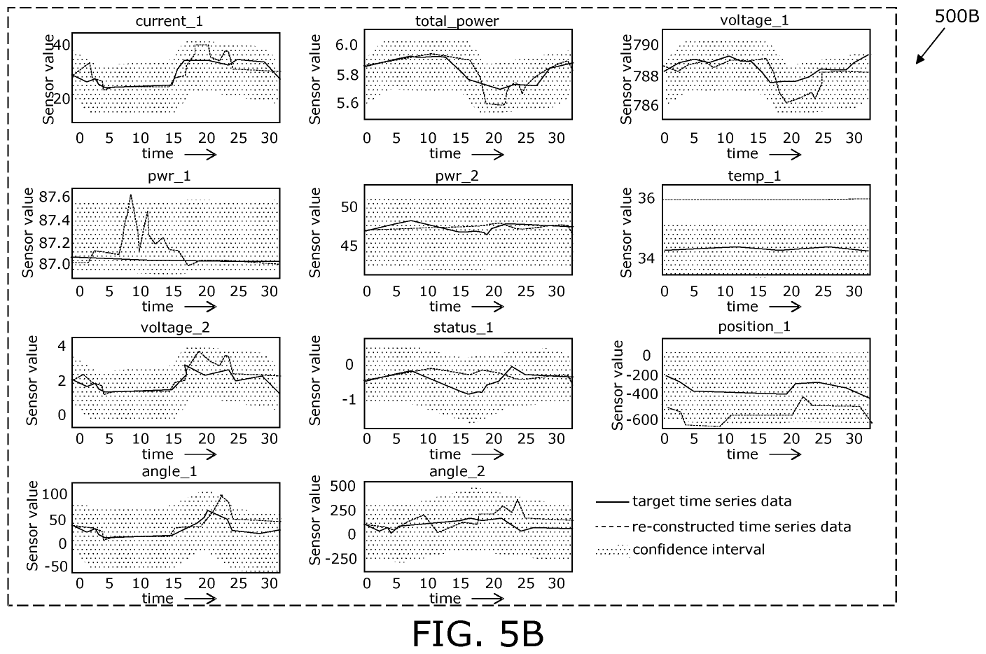

Referring to FIG. 5A, illustrated is an exemplary graphical illustration 500A of multiple target sensor time series data mapped to corresponding confidence interval for one of process cycle of the process being analysed. Herein, the graphical illustration 500A provides target sensor time series data mapped to corresponding confidence interval along with re-constructed sensor time series data for each of the variables thereof. As may be seen, in the graphical illustration 500A, for each of the variables, the target sensor time series data is substantially within the corresponding confidence interval, and thus it may be determined that the corresponding process cycle may not have any anomaly therein.

Referring to FIG. 5B, illustrated is an exemplary graphical illustration 500B of multiple target sensor time series data mapped to corresponding confidence interval for another of process cycle of the process being analysed. Herein, the graphical illustration 500B provides target sensor time series data mapped to corresponding confidence interval along with re-constructed sensor time series data for each of the variables thereof. As may be seen, in the graphical illustration 500B, for at least some of the variables, the target sensor time series data is substantially not within the corresponding confidence interval, and thus it may be determined that the corresponding process cycle may have some anomaly therein.

Modifications to embodiments of the present disclosure described in the foregoing are possible without departing from the scope of the present disclosure as defined by the accompanying claims. Expressions such as “including”, “comprising”, “incorporating”, “have”, “is” used to describe and claim the present disclosure are intended to be construed in a non-exclusive manner, namely allowing for items, components or elements not explicitly described also to be present. Reference to the singular is also to be construed to relate to the plural.

1. A method for detecting an anomaly in sensor time series data of a sensing arrangement, via a processing unit, the method comprising:
implementing a neural network trained on training data comprising prior sensor time series data;
re-constructing a sample sensor time series data for a target time period using the trained neural network;
determining an anomaly score variable based on a re-construction error in the re-constructed sample sensor time series data, corresponding to each of a plurality of time instants in the target time period;
determining a confidence interval for the target time period based on a distribution of the determined anomaly score variable;
mapping a target sensor time series data, generated by the sensing arrangement corresponding to the target time period, to the determined confidence interval; and
indicating an anomaly in the target sensor time series data if the target sensor time series data is not substantially within the determined confidence interval,
wherein the anomaly score variable is determined based on a maximum absolute reconstruction error in the re-constructed sample sensor time series data.

2. The method according to claim 1, wherein re-constructing the sample sensor time series data using the neural network comprises predicting at least one variable and a corresponding timestamp for each of the plurality of time instants in the target time period.

3. The method according to claim 1, wherein the confidence interval for the trained neural network is determined based on a mean of the determined anomaly score variable and a standard deviation of the determined anomaly score variable.

4. The method according to claim 1, wherein the neural network is an autoencoder comprising an encoder and a decoder, and wherein the encoder is trained on the training data and the decoder is implemented to re-construct the sample sensor time series data.

5. The method according to claim 1, wherein the sensing arrangement comprises a plurality of sensor devices, and wherein the sensor time series data comprises sensor parameters with timestamps for each of the plurality of sensor devices.

6. A system comprising:
a sensing arrangement integrated with a statistical process control of a semiconductor manufacturing process, the sensing arrangement configured to generate sensor time series data for the process;
a neural network trained on training data comprising prior sensor time series data, the neural network configured to re-construct a sample sensor time series data for a target time period; and
a processing unit configured to:
determine an anomaly score variable based on a re-construction error in the re-constructed sample sensor time series data, corresponding to each of a plurality of time instants in the target time period;
determine a confidence interval for the target time period based on a distribution of the determined anomaly score variable;
map a target sensor time series data, generated by the sensing arrangement corresponding to the target time period, to the determined confidence interval; and
indicate an anomaly in the target sensor time series data if the target sensor time series data is not substantially within the determined confidence interval,
wherein the processing unit is configured to determine the anomaly score variable based on a maximum absolute reconstruction error in the re-constructed sample sensor time series data.

7. The system according to claim 6, wherein the neural network is configured to predict at least one variable and a corresponding timestamp for each of the plurality of time instants in the target time period, to re-construct the sample sensor time series data.

8. The system according to claim 6, wherein the processing unit is configured to determine the confidence interval for the trained neural network based on a mean of the determined anomaly score variable and a standard deviation of the determined anomaly score variable.

9. The system according to any of claim 6, wherein the neural network is an autoencoder comprising an encoder and a decoder, and wherein the encoder is trained on the training data and the decoder is implemented to re-construct the sample sensor time series data.

10. The system according to claim 6, wherein the sensing arrangement comprises a plurality of sensor devices, and wherein the sensor time series data comprises sensor parameters with timestamps for each of the plurality of sensor devices.

11. The system according to claim 6, wherein the indicated anomaly in the target sensor time series data is used to control the process.

12. A computer program product comprising computer executable program code stored on a non-transitory computer readable medium, which when executed by a processing unit causes a system to perform the method of claim 1.
